(19) United States
(12) Patent Application Publication
(10) Pub. No.: US 2007/0102283 A1
(43) Pub. Date: May 10, 2007

(54) PVD method to condition a substrate surface

(76) Inventors: Tae Kyung Won, San Jose, CA (US); Robert Bachrach, Burlingame, CA (US); John M. White, Hayward, CA (US); Wendell T. Blonigan, Pleasanton, CA (US)

Correspondence Address: PATTERSON & SHERIDAN, LLP, 3040 POST OAK BOULEVARD, SUITE 1500, HOUSTON, TX, 77056, US

(21) Appl. No.: 11/271,660

(22) Filed: Nov. 10, 2005

(51) Int. Cl. C23C 14/00

(52) U.S. Cl. 204/192.12

(57) ABSTRACT

A method for conditioning a surface of a substrate, particularly substrates useful in a fuel cell, is disclosed. In one aspect, a method is disclosed for treating a substrate to increase the substrate's resistance to acid etching. The method includes depositing a layer of etch-resistant material via a PVD process onto a surface of the substrate. The substrate may comprise a carbon composite material or a conductive polymer, among others. In one aspect, the layer of etch-resistant material is about 1000 Å thick or less. In another aspect, the layer of etch-resistant material is a TiN layer. In another embodiment, a method is provided for treating a surface of a substrate decrease the substrate's liquid contact angle. The method includes depositing a layer of hydrophilic material via a PVD process onto a surface of the substrate. In one aspect, the deposited material may be a low resistivity material.

### BACKGROUND OF THE INVENTION

1. Field of the Invention

Embodiments of the present invention generally relate to the deposition of thin films. More particularly, this invention relates to a process and apparatus for depositing a thin film onto a substrate surface to condition the substrate surface.

2. Description of the Related Art

Developing environmentally friendly energy sources has gained significant interest recently in various industries related to the generation of power and electricity. Various types of fuel cells can be used to directly produce electricity for a number of applications, such as portable electronics, cell phones, wireless devices, PDA's, cameras, portable players, computer notebooks, vehicles, stationary large size energy equipment, residential electricity and others. Since semiconductor machining technology can be easily utilized in fuel cell manufacturing, efficient production of electricity by fuel cells is feasible.

A fuel cell is an electrochemical device in which a gaseous or liquid fuel reacts with an oxidant to produce electricity. Generally, an electrolyte is sandwiched by two electrodes, an anode and a cathode, to form a fuel cell unit. A fuel, such as pure hydrogen or hydrogen reformed from any hydrocarbon fuel, is fed into the anode to be oxidized into a proton and an electron. An oxidant, such as air or oxygen, is flowed into the cathode to react with the proton, which has passed through the electrolyte and, in some cases, through a proton-permeable membrane. The electron forms a separate current that can be utilized to generate electricity before returning to the cathode to be reunited with the proton and the oxidant, resulting in by-products, such as heat and water. Each fuel cell unit is stacked or arranged together to form a fuel cell stack or module. A number of modules or fuel cell stacks are piled, and electrical terminals, electrical insulators and end plates are disposed at opposite ends of the pile of modules to collectively produce electricity.

Thus, the essentials of a fuel cell are very simple, leading to highly reliable and long-lasting electricity/energy generating applications. Fuel cells are also highly efficient, converting hydrogen fuel into useful energy at an efficiency rate as high as 55-60 percent, as compared to about 35 percent for combustion gas engines or alkaline batteries. Further, the by-product of the main fuel cell reaction, when hydrogen is the fuel, is pure water, which means the carbon dioxide (CO₂) emission of a fuel cell is essentially zero. Also, fuel cells are very quiet, even those with extra equipment (e.g., fuel pump, air pump, thermal control systems, etc.), making them suitable for both portable power applications and for large-scale power generation.

In order for a fuel cell to operate properly with high electrical output and reliability, the fuel gas, oxidizing gas and waste fluids, such as liquid water, must move freely through the channels and conduits (discussed in conjunction with FIGS. 2A and 2B below) inside the fuel cell without interruption under a wide variety of operating conditions. As such, the surface properties of any fuel cell parts must be conditioned to facilitate and enable this movement. For example, the surface of fuel cell parts should provide a low liquid contact angle to the electrolyte.

The liquid contact angle of a surface or material, also known as the wetting angle, is used to quantify how readily a drop of a given liquid will wet or bead up on the surface. FIG. 1 is a schematic cross-sectional view of a solid-liquid system 100 consisting of a droplet 105 on a solid 102. The contact angle 101 of solid-liquid system 100 is a measurement of the angle formed between the surface of solid 102 and the line 103 tangent to the radius 104 of droplet 105 on the solid 102 from the point of contact 106 with the solid 102. For ease of measurement of the contact angle 101, the solid 102 typically is a flat, horizontal surface, as shown in FIG. 1. The contact angle 101 will vary for different systems of liquids and solids, resulting from the interaction of the surface tension of the droplet 105 and the surface chemistry of the solid 102. When contact angle 101 is less than 90° for a solid-liquid system 100, good wetting is produced and the droplet 105 tends to spread across the surface of solid 102. When contact angle 101 is greater than 90°, wetting is poor, i.e., droplet 105 is repelled by the surface of solid 102, and droplet 105 tends to bead or shrink away from solid 102. For aqueous solutions, such as the electrolyte solution or liquid waste water in a fuel cell, a surface or material that creates a contact angle smaller than 90° is referred to as hydrophilic and a surface or material that creates a contact angle larger 90° than is referred to as hydrophobic. FIG. 1A shows a droplet 105a of an aqueous solution in contact with a solid surface 102a and forming a contact angle 101a that is greater than 90°. Solid surface 102a is considered highly hydrophobic. FIG. 1B shows a droplet 105b of an aqueous solution in contact with a solid surface 102b and forming a contact angle 101b that is equal to 90°. Droplet 105b demonstrates significant beading on solid surface 102b and therefore solid surface 102b is considered hydrophobic. FIG. 1C shows a droplet 105c of an aqueous solution in contact with a solid surface 102c and forming a contact angle 101c that is less than 90°. Droplet 105c spreads out across solid surface 102c, therefore solid surface 102c is considered hydrophilic.

In addition to a low liquid contact angle with the electrolyte, the surface of fuel cell parts should withstand by-product heat and cycles of temperature variation between low temperatures (e.g., −40° C.) and high temperatures (e.g., 100° C.). Furthermore, the surfaces of fuel cell parts must be resistant to chemical etching by acid, water (H₂O), oxygen (O₂) and any other chemicals in the electrolyte to ensure long part lifetime and long-term reliable operation. Also, because an acidic environment in the fuel cell may be created from the release of fluorine present in the membrane electrode assembly, a fuel cell part may need to be conditioned to resist etching by hydrofluoric acid. A typical membrane electrode assembly is described below in conjunction with FIGS. 2A and 2B.

Further, various parts of a fuel cell stack or module may need to provide good electrical contact when mated with other parts in the fuel cell, as well as possessing low bulk resistivity. This minimizes current loss between stacks of fuel cell units.

Thus, there is still a need for methods and apparatus for conditioning a surface of a substrate, such as a fuel cell part, to provide improved fluid contact angle, low acid etch rate, and low resistivity to the surface of the substrate.

### SUMMARY OF THE INVENTION

Embodiments of the invention generally provide a method for conditioning surfaces of a substrate, particularly a substrate useful in a fuel cell. In one aspect, a method is disclosed for treating a surface of a substrate useful in a fuel cell to increase the substrate's resistance to acid etching. The method includes depositing a layer of etch-resistant material via a physical vapor deposition (PVD) process onto a surface of the substrate. The substrate may comprise a carbon composite material, a conductive polymer, a metal alloy or graphite. The layer of etch-resistant material is deposited to a thickness to enhance resistance to acid corrosion with a wet etch rate of less than about 0.03 A/mm in the presence of about 10 ppm of hydrofluoric acid in water. In one aspect, the layer of etch-resistant material deposited on the surface of the substrate is about 1000 Å thick or less. In another aspect, the layer of etch-resistant material is a TiN layer.

In another embodiment, a method is provided for treating a surface of a substrate useful in a fuel cell to decrease the substrate's liquid contact angle. The method includes depositing a layer of hydrophilic material via a PVD process onto a surface of the substrate. The substrate may comprise a carbon composite material, a conductive polymer, a metal alloy or graphite. The layer of hydrophilic material is deposited to a thickness to reduce the substrate's liquid contact angle to less than about 50 degrees in an aqueous solution. In one aspect, the layer of hydrophilic material deposited on the surface of the substrate is about 1000 Å thick or less. In another aspect, the layer of hydrophilic material is a TiN layer.

In one aspect of the invention, the layer of material deposited by a PVD process may be a low resistivity material. For example, the deposited material layer may exhibit a resistivity of less than about 100 ohm-cm, such as less than about 10 ohm-cm, on the surface of a carbon composite substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (Prior Art) is a schematic cross-sectional view of a solid-liquid system consisting of a droplet on a solid.

FIG. 1A (Prior Art) illustrates a droplet of an aqueous solution in contact with a solid surface and forming a contact angle that is greater than 90°.

FIG. 1B (Prior Art) illustrates a droplet of an aqueous solution in contact with a solid surface and forming a contact angle that is equal to 90°.

FIG. 1C (Prior Art) illustrates a droplet of an aqueous solution in contact with a solid surface and forming a contact angle that is less than 90°.

FIG. 2A illustrates an exploded perspective view of a fuel cell stack that may benefit from the present invention.

FIG. 2B illustrates a schematic view of an exemplary fuel cell unit that may be used in a fuel stack.

FIG. 3 is a schematic cross-sectional view of a PVD system that may be used to perform aspects of the invention.

FIG. 4A illustrates a partial sectional view of the flow field surface of an anode separator plate.

FIG. 4B illustrates a partial sectional view of the flow field surface of an anode separator plate.

FIG. 5 illustrates a partial sectional view of the cooling channel surface of an anode separator plate.

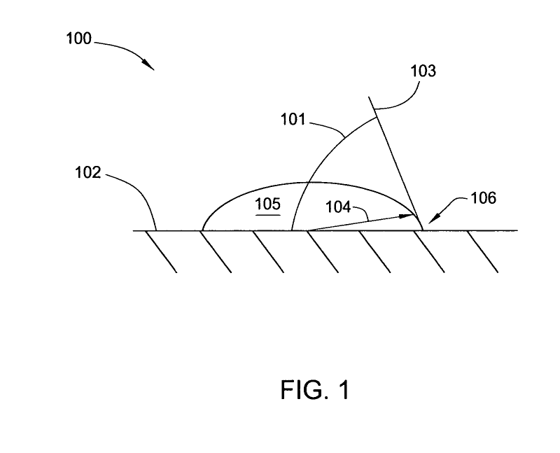

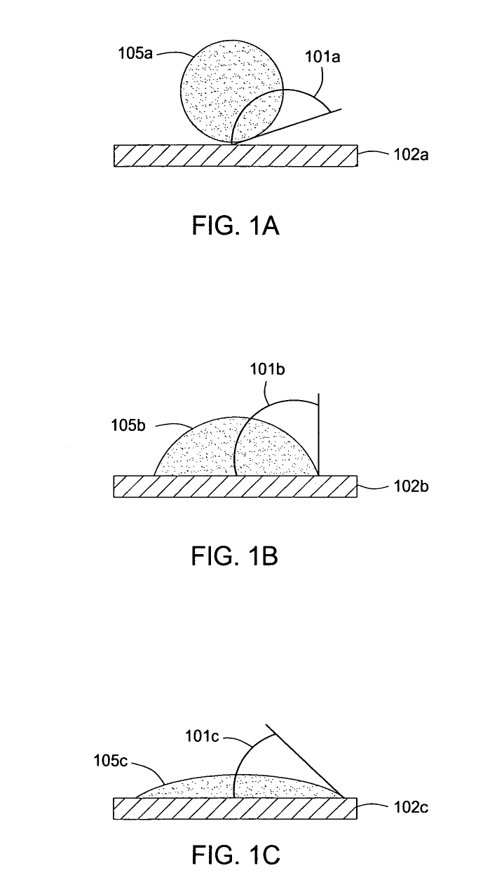

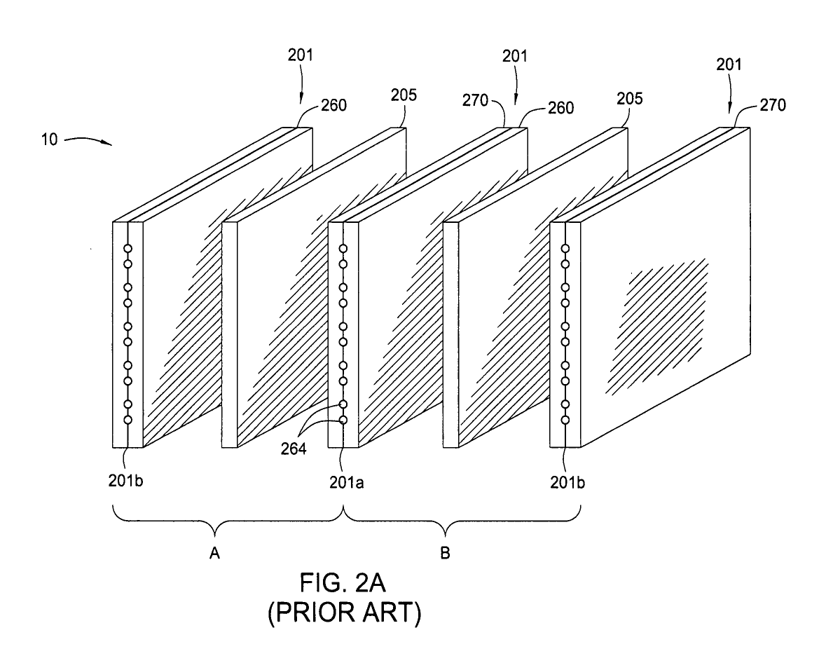

For clarity, identical reference numerals have been used, where applicable, to designate identical elements that are common between figures.

### DETAILED DESCRIPTION

The invention generally relates to a method of improving the surface properties of a substrate. The invention describes treating or conditioning a substrate surface by depositing a material layer with good adhesion to the substrate, a smaller fluid contact angle with the electrolyte than the untreated substrate surface, low electrical resistivity (high conductivity) and resistance to acid etching.

In one embodiment, the invention includes a process for conditioning various parts of a fuel cell by depositing a thin film having a consistent set of surface properties to promote the proper flow of gas and fluids through a fuel cell device. In addition, the deposited thin film resists dissolution or etching in acidic conditions, e.g., a diluted hydrofluoric acid environment, to provide high reliability of the fuel cell and long part lifetime. The thin film may be deposited to condition/treat any parts of a fuel cell, such as a conductive plate, separator plate, bipolar plate or end plate, among others.

Exemplary Fuel Cell

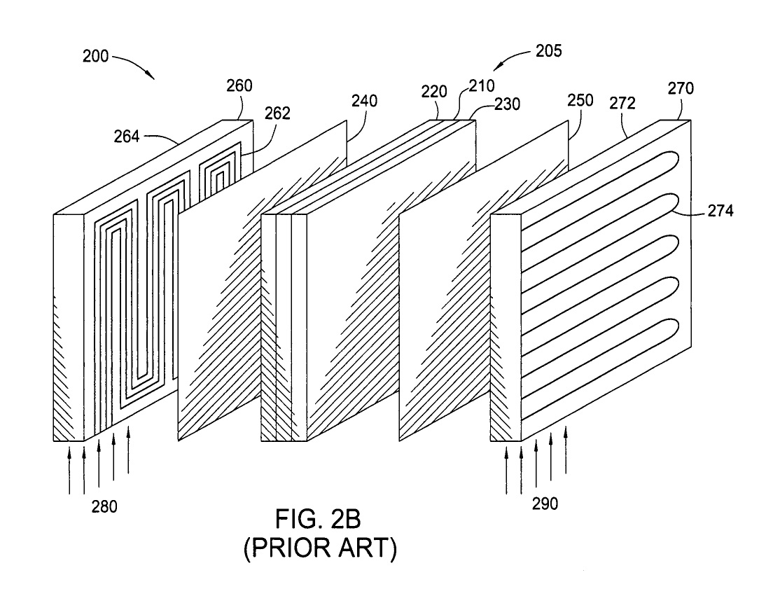

FIG. 2A illustrates an exploded perspective view of a fuel cell stack 10 that may benefit from the present invention. Fuel cell stack 10 consists of two fuel cell units: fuel cell unit A and fuel cell unit B. Generally, a fuel cell stack 10 uses a number of conductive plates 201 and membrane electrode assemblies 205. The conductive plates 201 are placed between adjacent fuel cell units in a fuel cell stack 10, such as fuel cell unit A and fuel cell unit B, to separate each fuel cell unit. A conductive plate placed between adjacent fuel cell units in a fuel cell stack is typically referred to as a separator plate 201a, or bipolar plate, and a conductive plate placed at either end of a fuel cell stack is called an end plate 201b. Each separator plate 201a generally includes an anode separator plate 260 and a cathode separator plate 270. A fuel cell stack typically has one end plate 201b that acts as an anode separator plate 260 and one end plate 201b that acts as a cathode separator plate 270, as illustrated in FIG. 2A. Anode separator plate 260 and cathode separator plate 270 usually include a series of flow channels or grooves, such as anode flow field 262 and cathode flow field 272, that distribute and route fuel gas or oxidant through a fuel cell unit. Anode flow field 262 and cathode flow field 272 are not shown in FIG. 2A, but are described in more detail below in conjunction with FIG. 2B. Referring back to FIG. 2A, each anode separator plate 260 or cathode separator plate 270 includes one side for flowing fuel gases or oxidant gases. The other side of each anode separator plate or cathode separator plate generally contains cooling channels or conduits. These conduits are mated with the cooling channels from an adjacent fuel cell unit in a fuel cell stack 10 to form a mated conductive plate, such as separator plate 201a, with internal cooling channels, such as cooling channels 264. Hence, separator plate 201a includes one side to serve as an anode for one fuel cell unit, such as fuel cell unit B, and a second side to act as a cathode for an adjacent fuel cell unit, such as fuel cell unit A.

FIG. 2B illustrates a schematic view of an exemplary fuel cell unit 200 that may be used in fuel stack 10, similar to fuel cell unit A or fuel cell unit B illustrated in FIG. 2A. A membrane 210 is generally sandwiched between an anode catalyst 220 and a cathode catalyst 230 to form a membrane electrode assembly 205. The membrane 210 can be made from ion exchange resins or a polymer material. For example, an ionic perfluorinated sulfonic acid polymer membrane, such as Nafion™, available from the E.I. DuPont de Nemours & Co. Other suitable membrane materials include Gore Select™, sulphonated fluorocarbon polymers, the polybenzimidazole (PBI) membrane (available from Celanese Chemicals, Dallas, Tex.), polyether ether ketone (PEEK) membranes and other materials. Various suitable catalyst formulations for the cathode catalyst 220 and the anode catalyst 230 are known in the art and are generally platinum-based with very finely divided catalytic particles supported on internal and external surfaces of a carbon binder, such as a polytetrafluorethylene (PTFE) binder.

The electrolyte plays a key role in a fuel cell to carry protons from one electrode, the anode, to the other electrode, the cathode. The electrolyte may include various types of organic and inorganic chemicals. Different types of fuel cells are formed depending on the types of chemicals used. In addition, the electrolyte may include a membrane, such as a polymer membrane for a direct methanol fuel cell (DMFC) or an immobilized liquid molten carbonate for a molten carbonate fuel cell (MCFC). One type of fuel cell, a proton exchange membrane fuel cell (PEMFC), uses a thin proton exchange membrane, such as membrane 210, with both sides of the surfaces coated with different catalysts, such as the cathode catalyst 220 and the anode catalyst 230, which accelerate the different chemical reactions at the anode and the cathode. The membrane is sandwiched by two microporous conductive layers (which function as the gas diffusion layers and current collectors) to separate the hydrogen fuel from the anode and the oxidant from the cathode, forming a membrane electrode assembly 205 as shown in FIG. 2B. In the exemplary fuel cell unit 200 illustrated in FIG. 2B, the two microporous conductive layers in membrane electrode assembly 205 are anode conductive gas diffusion layer 240 and a cathode conductive gas diffusion layer 250. Anode conductive gas diffusion layer 240 and a cathode conductive gas diffusion layer 250 serve as primary current collectors on each side of membrane electrode assembly 205. Both conductive gas diffusion layers are porous, gas-permeable and are generally made from paper or cloth-based carbon fibers, graphite materials or finely-meshed noble metal screens or foams, among other materials known in the art.

As illustrated in FIG. 2B, a pair of gas impermeable, non-porous, electrically conductive plates, such as an anode separator plate 260 and a cathode separator plate 270, is sandwiched between the primary current collectors, i.e., membrane electrode assembly 205, to serve as secondary current collectors for conducting current between adjacent fuel cells and at the ends of a fuel cell stack. The separator plates provide electrical contact between the anodes and cathodes of neighboring fuel cell units while preventing the hydrogen and oxygen reactant gases from mixing. Anode separator plate 260 and cathode separator plate 270 may be made of a metal alloy, such as stainless steel or aluminum protected with a corrosion-resistant conductive coating, or a conductive polymer, such as a carbon-filled composite, or other conductive compound, such as graphite. The carbon composite material provides the adequate electrical and thermal conductivity to be used as a separator. For example, a high-carbon composite with graphite powder in the range of 70% to 90% by volume can be used. However, these composite materials may be inherently brittle and dense, resulting in cracking and breaking. The separator plates in a fuel cell unit are continuously exposed to an acidic and polarized environment and to pressurized air and hydrogen. Further, the electrolyte of the fuel cell is generally in an environment containing up to 10 ppm of hydrofluoric acid, a strong etchant for many materials. The hydrofluoric acid is generated by the combination of protons produced at the anode and a small amount of fluorine ions released into the electrolyte by the fluorinated polymers of the separator plates. Thus, the separator plate must be resistant to such a hostile environment. Because of this, separator plates currently known in the art, such as an anode separator plate 260 and a cathode separator plate 270 may benefit from aspects of the invention, such as the application of a TiN coating.

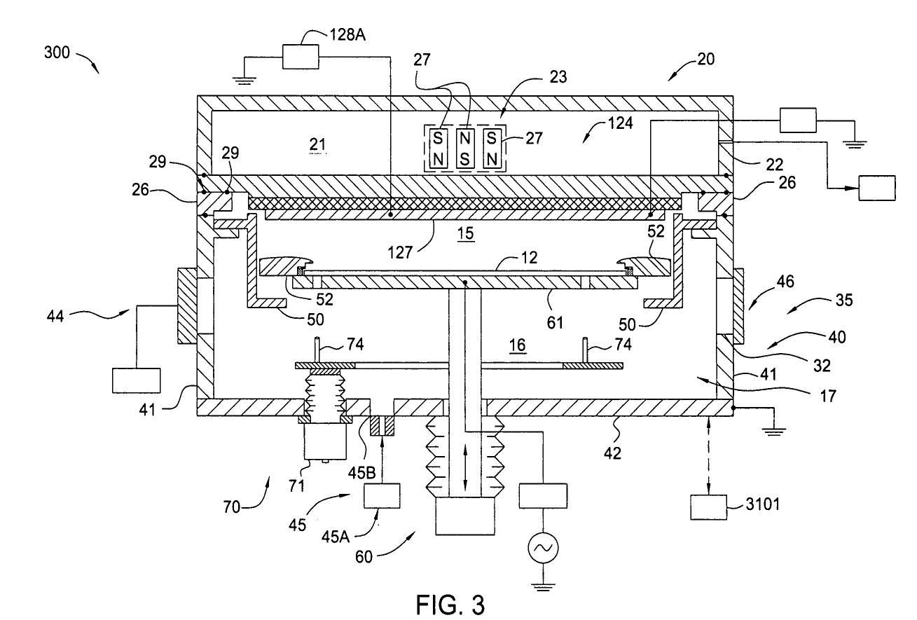

In one aspect of the invention, a PVD process is used to apply a durable conductive coating, such as a TiN coating, to the separator plates of a fuel cell, such as an anode separator plate 260 and a cathode separator plate 270. A TiN coating provides a more durable surface than the polymers and carbon composites generally used to construct separator plates and still possess very low resistivity. Such a non-friable surface extends fuel cell life and widens the conditions under which the fuel cell may operate. Further, the use of a PVD process (described below in conjunction with FIG. 3) ensures that a coating applied to the irregular surfaces of the separator plates, such as flow fields 262, 272, will have acceptable “step coverage”, i.e. uniform coverage by a coating of all features on a surface.

As noted above in conjunction with FIG. 2A and illustrated in FIG. 2B, one side of each separator plate contains a flow field consisting of a plurality of small channels, grooves, or passages. The anode separator plate 260 contains a flow field 262 that distributes and routes gaseous reactants, such as H₂ and other fuel gases, to the surface of the anode conductive gas diffusion layer 240, facing the anode side of membrane electrode assembly 205. The cathode separator plate 270 contains a flow field 272 that distributes and routes gaseous oxidants, such as O₂ or air, to the surface of the cathode conductive gas diffusion layer 250, facing the cathode side of membrane electrode assembly 205. The flow fields 262, 272 provide a means through which the gaseous reactants can flow between gas supplies 280, 290 leading into exemplary fuel cell unit 200 and gas exhausts (not shown) leading out of exemplary fuel cell unit 200.

The area between the plurality of flow channels contained in cathode separator plate 270 and anode separator plate 260 are generally called land areas which contact the primary current collector. The other sides of the anode and cathode separator plates 260 and 270, respectively, generally contain cooling channels 264 and 274 or other conduits for flowing a coolant. Typically, cooling channels 264, 274 are formed by mating two conductive plates together, such as cathode separator plate 270 and anode separator plate 260 of separator plate 201a, illustrated in FIG. 2A. Cooling channels 264, 274 form coolant paths to dissipate heat, water and other reaction by-products away from fuel cell unit, such as exemplary fuel cell unit 200, illustrated in FIG. 2B. The mated conductive plates become a separator plate or a bipolar plate to be placed between the anode of one fuel cell and a cathode of an adjacent fuel cell and, thus, the separator plate can be made out of one or more conductive plates. Alternatively, a bipolar plate can be made from one plate having cooling channels therein. In general, a bipolar plate includes one side for flowing a fuel gas through the flow field 262 and other side for flowing an oxidant through the flow field 272. Reactant gases from each side of the bipolar plate may pass along the flow fields 262, 272 and diffuse through the gas diffusion layers 240, 250 to reach the membrane electrode assembly 205.

The individual gas channels and passages contained in flow fields 262, 272 are generally small in relation to the overall size of the separator plates, i.e., on the order of 1 mm in width or diameter. Because the waste product of a fuel cell is commonly water, it is known in the art that the small gas channels inside flow fields 262, 272 are easily blocked by any water droplets that form inside them (see Visualization of Liquid Water Transport in a Polymer Electrolyte Fuel Cell, Electrochemical and Solid-State Letters, 7 (11) A408-A411, 2004). This type of blockage is referred to as electrode flooding. When electrode flooding blocks a gas channel at any point inside flow fields 262, 272, the fuel cell reaction for the entire gas channel is shut down, significantly reducing current produced by the fuel cell. It has been shown that the gravitation force on a water droplet approximately 1 mm in diameter is less by one order of magnitude than the surface tension of such a droplet. Because of this, different orientations (i.e. vertical instead of horizontal) of a fuel cell, or of the gas channels therein, will not significantly affect water droplet formation and, hence, electrode flooding. This is particularly true for more hydrophobic surfaces, such as the carbon-containing polymers typically used for separator plates in fuel cells. Instead, electrode flooding may be avoided by decreasing the liquid contact angle between the waste water produced in a fuel cell and the surfaces of the gas passages of flow fields 262, 272.

In one aspect of the invention, a PVD coating is applied to the flow field side of cathode separator plate 270 and anode separator plate 260. In this way, the liquid contact angle of the surfaces of the gas passages of flow fields 262, 272 may be reduced by the application of the hydrophilic PVD coating to some or all surfaces of the separator plates. An exemplary PVD process is described below in conjunction with FIG. 3. In one example, a PVD coating is only applied to the gas channel surfaces of cathode separator plate 270 and anode separator plate 260 to reduce the possibility of electrode flooding. In this case, the land areas, i.e. the current-transmitting surfaces located between the gas channels, are masked during the PVD process to prevent deposition thereon. When the hydrophilic coating has relatively high resistivity, masking the land areas minimizes contact resistance between adjacent separator plates, such as cathode separator plate 270 and anode separator plate 260 of separator plate 201a, illustrated in FIG. 2A. In another example, a low resistivity PVD coating, such as a TiN coating, is applied to all flow field surfaces of cathode separator plate 270 and anode separator plate 260. In this case, no masking of the land areas of the separator plates is required because no significant contact resistance between adjacent separator plates is created by the low resistivity PVD coating. In yet another example, a low resistivity PVD coating, such as a TiN coating, is applied to all cooling channel surfaces of cathode separator plate 270 and anode separator plate 260. In this case, the formation of a hydrophilic surface on the cooling channel surfaces reduces the possibility of any cooling channels being blocked by a “vapor lock” scenario, i.e. when a heated liquid begins turning to vapor in a narrow conduit and blocks the flow of liquid. This is because vapor bubbles are less likely to adhere to hydrophilic surfaces. Vapor bubbles adhering to the walls of a narrow conduit restrict liquid flow through the conduit, such as through cooling channels 264, 274. As the liquid flow is reduced, vaporization of the heated liquid increases, until a vapor lock is created.

Exemplary PVD Apparatus and Process

As noted above, a number of components of a fuel cell may benefit by being coated with a durable, conductive (i.e., low-resistivity) material that reduces the liquid contact angle of a component's surface and is resistant to etching by dilute hydrofluoric and other acids. A PVD TiN film is such a coating. A method and apparatus for the application of a PVD TiN film to improve the surface properties of fuel cell components is described below in conjunction with FIG. 3.

One embodiment is illustratively described below in reference to a physical vapor deposition (PVD) system configured to process different types of substrates, such as various PVD systems available from AKT, a division of Applied Materials, Inc., Santa Clara, Calif. However, it should be understood that the invention has utility in other system configurations, such as other PVD systems and any other film deposition systems, including those systems configured to process round substrates.

Physical vapor deposition using a magnetron is one of the principal methods of depositing a metal layer of uniform thickness onto a substrate. During a PVD process a target is electrically biased so that ions generated in a process region can bombard the target surface with sufficient energy to dislodge atoms from the target. The process of biasing a target to cause the generation of a plasma that in turn causes ions to bombard and remove atoms from the target surface is commonly called sputtering. The sputtered atoms travel generally ballistically toward the substrate being sputter-coated and the sputtered atoms are deposited on the substrate. Alternatively, the atoms may react with another gas in the plasma, for example, nitrogen, to reactively deposit a compound on the wafer. Reactive sputtering is often used to form layers of titanium nitride or tantalum nitride.

DC magnetron sputtering is the most usually practiced commercial form of sputtering. The metallic target is biased to a negative DC bias in the range of about −400 to −600 VDC to attract positive ions of the working gas (e.g., argon or an argon-nitrogen mixture) toward the target to sputter the metal atoms. Usually, the sides of the sputter reactor are covered with a shield to protect the chamber walls from sputter deposition. The shield is typically electrically grounded and thus provides an anode in opposition to the target cathode to capacitively couple the DC target power into the chamber and its plasma.

A magnetron having at least a pair of opposed magnetic poles is typically disposed near the back of the target to generate a magnetic field close to and parallel to the front face of the target. The induced magnetic field from the pair of opposing magnets trap electrons and extend the electron lifetime before they are lost to an anodic surface or recombine with gas atoms in the plasma. Due to the extended lifetime, and the need to maintain charge neutrality in the plasma, additional argon ions are attracted into the region adjacent to the magnetron to form there a high-density plasma. Thereby, the sputtering rate is increased.

FIG. 3 illustrates a vertical cross-sectional view of one embodiment of a processing chamber 300 that may be used to perform aspects of the invention described herein. In general, the processing chamber 300 contains a lid assembly 20 and a lower chamber assembly 35. The lower chamber assembly 35 generally contains a substrate support assembly 60, chamber body assembly 40, a shield 50, a process gas delivery system 45 and a shadow frame 52. The shadow frame 52 is generally used to shadow the edge of a substrate 12 to prevent or minimize the amount of deposition on the edge of the substrate 12 and substrate support 61 during processing. The chamber body assembly 40 generally contains one or more chamber walls 41 and a chamber base 42. The one or more chamber walls 41, the chamber base 42 and a surface of the target assembly 124 generally form a vacuum processing area 17 that has a lower vacuum region 16 and a processing region 15. The process gas delivery system 45 generally contains one or more gas sources 45A that are in fluid communication with one or more inlet ports 45B that are in direct communication with the lower vacuum region 16 and/or the processing region 15, to deliver a process gas that can be used during the plasma process. FIG. 3 illustrates a substrate 12 that is positioned in a processing position on substrate support 61 in the processing region 15.

The lower chamber assembly 35 will also generally contain a substrate lift assembly 70, slit valve 46 and vacuum pumping system 44. The lift assembly 70 is adapted to remove and replace a substrate positioned on a robot blade (not shown) that has been extended into the lower chamber assembly 35 from a central transfer chamber (not shown). The extended robot blade enters the lower chamber assembly 35 through the access port 32 in the chamber wall 41 and is positioned above the substrate support 61 that is positioned in a transfer position (not shown).

The vacuum pumping system 44 evacuates the lower vacuum region 16 and processing region 15 to a desired base and/or processing pressure. A slit valve actuator (not shown) which is adapted to position the slit valve 46 against or away from the one or more chamber walls 41 may be a conventional pneumatic actuator which is well known in the art.

To control the various processing chamber 300 components and process variables during a deposition process, a controller 3101 is used. The processing chamber's processing variables may be controlled by use of the controller 3101, which is typically a microprocessor-based controller. The controller 3101 is configured to receive inputs from a user and/or various sensors in the plasma processing chamber and appropriately control the plasma processing chamber components in accordance with the various inputs and software instructions retained in the controller's memory.

The lid assembly 20 generally contains a target assembly 124, a lid enclosure 22, a ceramic insulator 26, one or more o-ring seals 29 and a magnetron assembly 23 that is positioned in a target backside region 21. Generally, each magnetron assembly 23 will have at least one magnet 27 that has a pair of opposing magnetic poles (i.e., north (N) and south (S)) that create a magnetic field (B-field) that passes through the target assembly 124 and the processing region 15. An exemplary magnetron assembly that may be adapted to benefit the invention described herein is further described in the commonly assigned U.S. patent application Ser. No. 10/863,152[APPM 8841], filed Jun. 7, 2004, which claims the benefit of U.S. Provisional Patent Application Ser. No. 60/534,952, filed Jan. 7, 2004, and is hereby incorporated by reference in its entirety to the extent not inconsistent with the claimed invention.

To perform a PVD deposition process on a substrate 12, such as a conductive plate 201 used in fuel cell stack 10, illustrated in FIG. 2A, the controller 3101 commands the vacuum pumping system 44 to evacuate the processing chamber 300 to a predetermined pressure/vacuum. Chamber evacuation allows the processing chamber 300 to receive a substrate 12 from a system robot (not shown) mounted to a central transfer chamber (not shown) which is also under vacuum. To transfer a substrate 12 to the processing chamber 300, the slit valve 46, which seals off the processing chamber 300 from the central transfer chamber, opens to allow the system robot to extend through the access port 32 in the chamber wall 41. The lift pins 74 of substrate lift assembly 70 then remove the substrate 12 from the extended system robot, by lifting the substrate from the extended robot blade (not shown) using a lift actuator 71. The system robot then retracts from the processing chamber 300 and the slit valve 46 closes to isolate the processing chamber 300 from the central transfer chamber. The substrate support 61 then lifts the substrate 12 from the lift pins 74 and moves the substrate 12 to a desired processing position below the target assembly 124. After achieving a desired base pressure, (e.g., 10⁻⁶ to 10⁻⁹ Torr) by use of the vacuum pumping system 44, a desired flow of a processing gas is injected into the processing region 15 and a bias voltage is applied the target region 127 of the target assembly 124 by use of a power supply 128A attached to the target region. The application of a bias voltage by the power supply causes the gas in the processing region 15 to become ionized and bombard the surface of the cathodically biased target region 127 and thus “sputter” metal atoms that land on the surface of the substrate 12. For the formation of a TiN film on the substrate surface, the process gas is typically a nitrogen or nitrogen-argon mixture. The flow rate of process gas varies as a function of chamber size, ranging from about 100 sccm for a chamber with a processing region 15 that is 200 mm in diameter to 20,000 sccm for chamber with a processing region 15 that is 1300 mm×1500 mm in area. One skilled in the art can readily determine an appropriate process gas mixture and flow rate, depending on the size of PVD chamber and deposition rate desired.

PREFERRED EMBODIMENT

In one aspect of the invention, surfaces inside a fuel cell that may benefit from a conditioning or protective coating, such as a TiN coating, include the flow field side of a separator plate, such as anode separator plate 260 and a cathode separator plate 270 contained in fuel cell unit 200 and illustrated in FIG. 2B. Because the conductive plates in fuel cell unit 200 are generally composed of brittle and/or non-durable materials, such as graphite, carbon-composites, or polymers, for example, a durable conductive coating, such as TiN may greatly improve their operational lifetime. Further, TiN is resistant to etching by hydrofluoric acid, which is commonly present inside fuel cells in concentrations up to about 10 ppm.

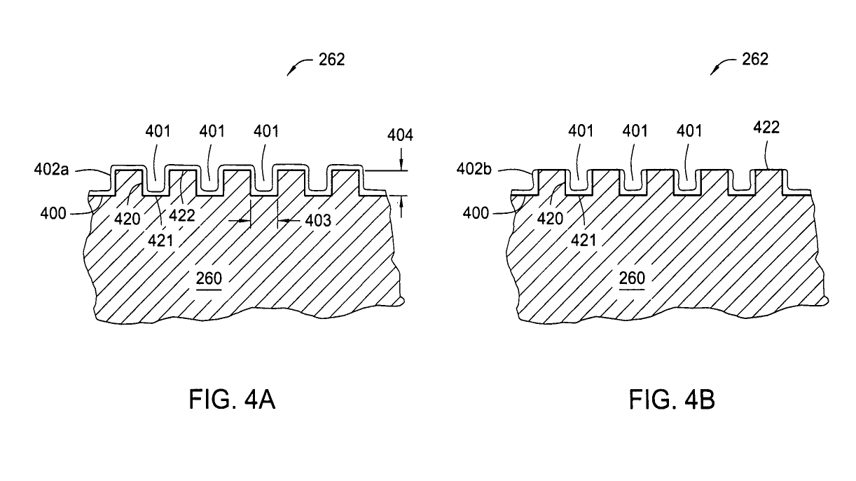

FIG. 4A illustrates a partial sectional view of the flow field surface 400 of an anode separator plate 260, which is also illustrated in FIGS. 2A and 2B. Gas channels 401 contained in flow field 262 are shown in cross-section. A PVD coating 402a is depicted on anode separator plate 260 as covering the entire flow field surface 400 of anode separator plate 260. This includes not only the sides 420 and bottom 421 of gas channels 401, but also the land areas 422. As illustrated in FIG. 2B and 4B, the land areas 422 of anode separator plate 260 are designed to contact anode conductive gas diffusion layer 240 when the fuel cell is assembled. In this aspect, no masking is used to prevent deposition of PVD coating 402a on the land areas 422. When PVD coating 402a consists of a TiN coating, very little additional electrical resistance is introduced into the fuel cell when the land areas are also coated. This is due to the low resistivity of a PVD TiN coating; TiN possesses high bulk conductivity (less than about 10 ohm-cm) and a PVD TiN coating on a separator plate is also very thin. It is important to note that the TiN coating, i.e. PVD coating 402a, is illustrated in FIG. 4A with a greatly exaggerated thickness relative to the size of the gas channels. Typically, the width 403 and depth 404 of gas channels 401 is on the order of about 1 mm. In contrast, the thickness required for a TiN coating to provide adequate protection of flow field surface 400 is on the order of about 1000 Å or less—four orders of magnitude smaller in size than gas channels 401. Due to the high resistance to etching of TiN, a thicker coating is not required.

In one example of this aspect, a PVD coating 402b is only deposited on the internal gas channel surfaces of a flow field 262 on a separator plate, such as an anode separator plate. This is illustrated in FIG. 4B. The internal gas channel surfaces that are treated with PVD coating 402b include the sides 420 and bottom 421 of gas channels 401. Masking material placed on the land areas 422 is used to prevent deposition of the PVD coating thereon. In this example, a PVD coating that is not as conductive as TiN may be used to protect and reduce the liquid contact angle of the sides 420 and bottom 421 of gas channels 401 without introducing additional electrical resistance between the conductive plates of a fuel cell. For example, the resistivity of PVD coating 402b in this example may be as high as about 100 ohm-cm.

In another aspect of the invention, the cooling channel side of a separator plate, such as anode separator plate 260 or cathode separator plate 270 (illustrated in FIG. 2B) is coated with a layer of material deposited via a PVD process. In one example, the PVD coating is a TiN coating. The increased wettability, i.e., smaller liquid contact angle, created thereby may improve the performance of the cooling channels by reducing the possibility of vapor lock occurring in the cooling channels 264 formed into the separator plate. Further, the TiN coating may significantly increase the durability and acid resistivity of the separator plate surface and, hence, increase the operational lifetime of the separator plate as well.

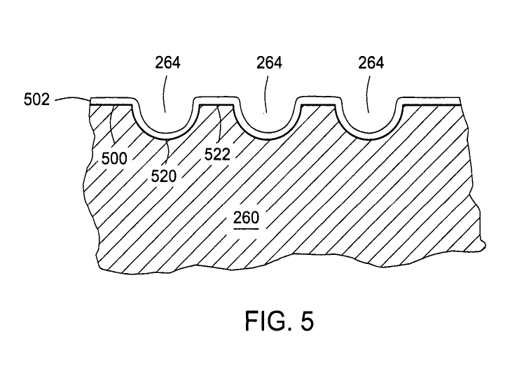

FIG. 5 illustrates a partial sectional view of the cooling channel surface 500 of an anode separator plate 260, which is also illustrated in FIGS. 2A and 2B. Cooling channels 264 are shown in cross-section. A PVD coating 502 is depicted on anode separator plate 260 as covering the cooling channel surface 500 of anode separator plate 260. This includes the bottom 520 and the land areas 522 of the cooling channels 264. Alternatively, masking may be applied to the land areas 522 to prevent deposition of PVD coating 502 thereon. In order to condition the cooling channel surface 500 against acid etching and to provide a durable coating, the thickness of PVD coating 502, when a TiN coating, may be relatively thin, for example no thicker than about 1000 Å. This is adequate to protect the material of an anode separator plate 260 or cathode separator plate 270 from the hostile environment of the fuel cell interior.

Other surfaces inside a fuel cell, particularly surfaces that are preferably highly conductive yet highly acid resistant, may also benefit from a TiN coating. A thin film, i.e. less than about 1000 Å, may be deposited via a PVD process to condition any parts of a fuel cell that are routinely exposed to the acidic environment, such as the end plates, the fuel cell housing and the fuel gas and oxidant gas supply and exhaust conduits, among others.

In another aspect, a surface undergoes a pre-clean process prior to deposition of the PVD coating. One example of a beneficial pre-clean process is a plasma-clean process, also known as a sputter clean process. Another example is a wet clean process. Either process may be performed on the desired fuel cell surface in order to remove unwanted contamination present on a fuel cell surface that may subsequently result in the delamination or peeling of the PVD coating from the treated fuel cell surface.

A plasma-clean process may be performed in a plasma-processing chamber immediately prior to deposition of the PVD film. Preferably, the plasma-clean process is performed on the fuel cell surface without removing the treated surface from vacuum and exposing it to atmospheric conditions. Exposure to atmosphere may be avoided between a plasma-clean process and a PVD process when the PVD processing chamber and the plasma-processing chamber share access to a common central transfer chamber that is also maintained at vacuum. By keeping the fuel cell surface at vacuum between the surface cleaning process and the deposition process, contamination of the fuel cell surface is minimized and adhesion of the PVD coating is improved.

A plasma-clean process may be performed in a chamber that is inductively coupled, capacitively coupled or utilizes a remote plasma source. The application of reactive gases, such as ammonium or nitrogen trifluoride, for example, may also be used as part of the plasma-clean process to enhance the cleaning of the fuel cell surface. As part of the plasma-clean process, the selection of chemical species, process gas flow rates and plasma power are strongly dependent on the composition of the substrate being processed. The plasma-clean process is well known in the art and anyone skilled in the art may select an appropriate cleaning method for a given fuel cell surface.

A wet-clean process may also be performed in a plasma-processing chamber immediately prior to deposition of the PVD film. The wet-clean process may be performed on fuel cell components singly or in batches. Chemical selection, cleaning time, cleaning bath temperature, rinse times and other process details are dependent on the composition of the surface being cleaned. The wet-clean process is well known in the art and anyone skilled in the art may select the appropriate cleaning method for a given fuel cell surface.

Fuel cell components that may benefit from the invention may be of any shape, e.g., circular, square, rectangle, polygonal, etc., and size. Also, the composition of fuel cell components is not limiting and can be any substrate comprised of a material of carbon-containing polymer, composite, metal, plastic, or glass, particularly where the substrate's surface fluid contact angle and resistance to wet etch conditions need to be improved while maintaining good conductivity, i.e., low resistivity.

Although several preferred embodiments which incorporate the teachings of the present invention have been shown and described in detail, those skilled in the art can readily devise many other varied embodiments that still incorporate these teachings.

While the foregoing is directed to embodiments of the present invention, other and further embodiments of the invention may be devised without departing from the basic scope thereof, and the scope thereof is determined by the claims that follow.

1. A method of forming a fuel cell, comprising:
providing at least one membrane electrode assembly, at least one cathode separator plate having a first surface that has a first liquid contact angle and at least one anode separator plate having a second surface that has a second liquid contact angle;
modifying the first surface and the second surface by depositing a layer of material thereon by a PVD process, the layer of material having a third liquid contact angle, wherein the third contact angle is smaller than the first liquid contact angle and the second liquid contact angle; and
assembling the cathode separator plate, the anode separator plate and the membrane electrode assembly to form a fuel cell.

2. The method of claim 1, wherein the first surface and the second surface comprise a material selected from a group consisting of graphite, a carbon-filled composite, a conductive polymer and combinations thereof.

3. The method of claim 1, wherein the third liquid contact angle is less than about 50 degrees.

4. The method of claim 1, wherein the layer of material comprises a resistivity of less than about 100 ohm-cm.

5. The method of claim 1, wherein the layer of material has an etch rate of less than about 0.03 Å/min in the presence of about 10 ppm of hydrofluoric acid in water.

6. The method of claim 1, wherein the layer of material is a layer of titanium nitride.

7. A method of forming a fuel cell, comprising:
providing at least one membrane electrode assembly, at least one cathode separator plate comprised of a material having a first etch rate in the presence of about 10 ppm hydrofluoric acid in water, and at least one anode separator plate comprised of a material having a second etch rate in the presence of about 10 ppm hydrofluoric acid in water;
modifying the surface of the cathode separator plate and the anode separator plate by depositing a layer of material by a PVD process, wherein the layer of material has a third etch rate in the presence of about 10 ppm hydrofluoric acid in water, the third etch rate being smaller than the first etch rate and the second etch rate; and
assembling the cathode separator plate, the anode separator plate and the membrane electrode assembly to form a fuel cell.

8. The method of claim 7, wherein the cathode separator plate and the anode separator plate comprise a material selected from a group consisting of graphite, a carbon-filled composite, a conductive polymer and combinations thereof.

9. The method of claim 7, wherein the surface of the layer of material has a liquid contact angle that is less than about 50 degrees.

10. The method of claim 7, wherein the layer of material comprises a resistivity of less than about 100 ohm-cm.

11. The method of claim 7, wherein the third etch rate is less than about 0.03 Å/min.

12. The method of claim 7, wherein the layer of material is a layer of titanium nitride.

13. A method for treating a surface of a fuel cell component having a first liquid contact angle, comprising:
positioning a fuel cell component in a processing chamber, the fuel cell component having a first liquid contact angle; and
depositing a layer of material onto a surface of the fuel cell component using a physical vapor deposition process, the surface of the layer having a smaller liquid contact angle than the first liquid contact angle.

14. The method of claim 13, wherein the surface of the fuel cell component comprises a material selected from a group consisting of graphite, a carbon-filled composite, a conductive polymer and combinations thereof.

15. The method of claim 13, wherein the surface of the layer of material has a liquid contact angle that is less than about 50 degrees.

16. The method of claim 13, wherein the layer of material comprises a resistivity of less than about 100 ohm-cm.

17. The method of claim 13, wherein the etch rate of the layer of material is less than about 0.03 Å/min in the presence of about 10 ppm of hydrofluoric acid in water.

18. The method of claim 13, wherein the layer of material is a layer of titanium nitride.

19. A method of reducing the liquid contact angle of a substrate having a first liquid contact angle, comprising:
positioning a substrate in a processing chamber, the substrate having a first liquid contact angle; and
depositing a layer of material onto a surface of the substrate using a physical vapor deposition process, the surface of the layer having a smaller liquid contact angle than the first liquid contact angle.

20. The method of claim 19, wherein the surface of the substrate comprises a material selected from a group consisting of graphite, a carbon-filled composite, a conductive polymer and combinations thereof.

21. The method of claim 13, wherein the layer of material comprises a resistivity of less than about 100 ohm-cm.

22. The method of claim 19, wherein the etch rate of the layer is less than about 0.03 Å/min in the presence of about 10 ppm of hydrofluoric acid in water.

23. The method of claim 19, wherein the layer of material is a layer of titanium nitride.
